(19) United States
(12) Patent Application Publication
(10) Pub. No.: US 2025/0280664 A1
(43) Pub. Date: Sep. 4, 2025

(54) DISPLAY PANEL AND DISPLAY DEVICE

(71) Applicant: HKC CORPORATION LIMITED, SHENZHEN (CN)

(72) Inventors: Qin LIANG, SHENZHEN (CN); Yangling TANG, SHENZHEN (CN); Zhisheng XIE, SHENZHEN (CN); Zhi YANG, SHENZHEN (CN); Lidan YE, SHENZHEN (CN)

(73) Assignee: HKC CORPORATION LIMITED, SHENZHEN (CN)

(21) Appl. No.: 19/031,447

(22) Filed: Jan. 18, 2025

(30) Foreign Application Priority Data
Feb. 29, 2024 (CN) 202410234261.3

(51) Int. Cl. H10K 59/122; H10K 59/121

(52) U.S. Cl. CPC H10K 59/122; H10K 59/121

(57) ABSTRACT

The present application provides a display panel and a display device. In the present application, electrical connections between the cathodes of the plurality of sub-pixels are achieved through the plurality of isolation structure. On this basis, the plurality of side walls of each isolation structure are divided into the first side wall and the second side wall. An area enclosed by an outer wall of each isolation structure remains unchanged, the thickness of the first side wall remains unchanged, and the thickness of the second side wall is narrowed or reduces.

### CROSS-REFERENCE TO RELATED APPLICATIONS

The present application claims priority to Chinese Patent Application No. 202410234261.3, entitled “DISPLAY PANEL AND DISPLAY DEVICE”, filed Feb. 29, 2024, which is herein incorporated by reference in its entirety.

### TECHNICAL FIELD

The present disclosure relates to the field of display technologies, and in particular to a display panel and a display device.

### BACKGROUND

At present, organic light-emitting diodes (OLEDs) are prepared by evaporating using fine masks. The fine masks are expensive, so that it is costly to develop new products. Furthermore, a bridging area of openings of the fine mask also limits an effective area of a pixel light-emitting area for evaporation, which does not facilitate improvement of an opening rate.

### SUMMARY OF THE DISCLOSURE

A first technical solution in the present disclosure is to provide a display panel. The display panel includes a pixel definition layer and a plurality of pixel units.

The pixel definition layer defines a plurality of pixel openings.

Each of the plurality of pixel units includes a plurality of sub-pixels and a plurality of isolation structures.

The plurality of sub-pixels are arranged in the plurality of pixel openings one-to-one.

The plurality of isolation structures protrude from the pixel definition layer and respectively surround the plurality of pixel openings. A plurality of side walls of each of the plurality of isolation structures are defined as a first side wall and a second side wall, respectively. In a direction parallel to the pixel definition layer, a thickness of the first side wall is greater than that of the second side wall. In each of the plurality of isolation structures, the first side wall includes at least a portion of the side walls extending along a first direction and/or at least a portion of the side walls extending along a second direction.

In each of the plurality of pixel units, the first side wall of at least one isolation structure at least includes an inclined side wall; an extension direction of the inclined side wall intersects with the first direction and the second direction, respectively; and the first direction is perpendicular to the second direction, the extension direction of the inclined side wall, the first direction, and the second direction are located in the same plane.

A cathode of each of the plurality of sub-pixels is electrically connected to corresponding inclined side wall, so that the cathode of each of the plurality of sub-pixels is electrically connected to a corresponding one of the plurality of isolation structures; and/or, the cathode of each of the plurality of sub-pixels is electrically connected to corresponding side wall extending along the first direction, so that the cathode of each of the plurality of sub-pixels is electrically connected to the corresponding one of the plurality of isolation structures.

In some embodiments, each of the plurality of isolation structures surrounds a corresponding one of the plurality of pixel openings; there is a one-to-one correspondence between the plurality of side walls of each of the plurality of isolation structures and side edges of each of the plurality of sub-pixels enclosed by the each of the plurality of isolation structures, and the plurality of side walls of the plurality of isolation structures are respectively parallel to the side edges of the plurality of sub-pixels.

Each of the plurality of sub-pixels includes an anode, a light-emitting layer, and a cathode sequentially stacked; the light-emitting layer and the cathode are sequentially formed on an upper surface of the anode by evaporating an evaporation source; and the first direction is a long side direction of the evaporation source, and the second direction is a moving direction of the evaporation source.

In some embodiments, each of the plurality of pixel units includes at least one pixel group, at least one sub-pixel and one of the plurality of isolation structures surrounding corresponding sub-pixel form a pixel group, a shape of each pixel group is a hexagon, the hexagon has an axisymmetric or centrosymmetric shape, and each pixel group includes a side edge extending along the first direction or the second direction.

Each of the plurality of pixel units includes a plurality of pixel groups, the plurality of pixel groups are disposed side by side and in direct contact with each other along the first direction or the second direction, and a side of one pixel group and a side of an adjacent pixel group close to the side of the pixel group are parallel to each other.

In some embodiments, the plurality of pixel units are repeated and disposed side by side in the first direction to form a pixel unit row, and a plurality of pixel unit rows are repeated in the second direction.

Alternatively, the plurality of pixel units are defined as a first pixel unit and a second pixel unit, respectively; the second pixel unit is formed by centrally or axially symmetrizing the first pixel unit; a plurality of first pixel units are repeatedly arranged along the first direction, to form a first pixel unit row; a plurality of second pixel units are repeatedly arranged along the first direction, to form a second pixel unit row; and the first pixel unit row and the second pixel unit row are alternately arranged along the second direction.

In some embodiments, in the pixel unit, a side of one of the plurality of sub-pixels and a side of an adjacent sub-pixel close to the side of the one of the plurality of sub-pixels are parallel to each other.

Each pixel group includes an inclined side edge and a side edge extending along the second direction, and an extension direction of the inclined side edge intersects with the first direction and the second direction; each of the plurality of pixel units includes three sub-pixels of different colors, which are defined as a first sub-pixel, a second sub-pixel, and a third sub-pixel, respectively; the first sub-pixel and one of the plurality of isolation structures surrounding the first sub-pixel form a first pixel group; the second sub-pixel, one of the plurality of isolation structures surrounding the second sub-pixel, the third sub-pixel, and one of the plurality of isolation structures surrounding the third sub-pixel form a second pixel group; in the second pixel group, the third sub-pixel and the second sub-pixel share a side wall of the plurality of isolation structures extending along the first direction, and the third sub-pixel is flush with the second sub-pixel in the second direction; and side walls extending along the second direction of two adjacent isolation structures in the first direction overlap in a direction perpendicular to the pixel definition layer.

In some embodiments, in each of the plurality of isolation structures, the first side wall includes all inclined side walls; in the first direction, two adjacent first side walls are in direct contact with each other and electrically connected to each other.

In each of the plurality of isolation structures, the first side wall includes the side walls extending along the second direction and a portion of the inclined side walls; in the second direction, every two first side walls of a plurality of first side walls are in direct contact with each other, so as to form a plurality of side wall groups; the plurality of side wall groups are configured to electrically connect two adjacent pixel groups in the second direction; and in the first direction, the plurality of side wall groups are spaced apart from each other.

In some embodiments, in the second pixel group, the first side wall of each of the plurality of isolation structures further includes a side wall extending along the first direction.

In some embodiments, each of the plurality of side walls of each of the plurality of isolation structures includes an isolation column and an eave structure disposed on an upper surface of isolation column, and the eave structure covers the isolation column and extends out of the isolation column in the direction parallel to the pixel definition layer; and the eave structure is conductive or insulating, and the isolation column of the first side wall is conductive and configured for being electrically connected to one of the plurality of sub-pixels that is enclosed by the corresponding one of the plurality of isolation structures.

In some embodiments, the isolation column of the second side wall is conductive.

Alternatively, the isolation column of the second side wall is insulating, and the isolation column of the second side wall and the pixel definition layer are formed by patterning the same insulating material.

In some embodiments, an area of an orthographic projection of the eave structure on the pixel definition layer is greater than an area of an orthographic projection of the isolation column on the pixel definition layer.

A second technical solution in the present disclosure is to provide a display device including the display panel of any one of above embodiments.

### BRIEF DESCRIPTION OF THE DRAWINGS

In order to more clearly illustrate the technical solutions in some embodiments of the present disclosure, hereinafter, a brief introduction may be given to the accompanying drawings that are used in the description of some embodiments. Obviously, the accompanying drawings in the description below are merely some embodiments of the present disclosure. For those of ordinary skill in the art, other accompanying drawings may be obtained based on these accompanying drawings without any creative efforts.

FIG. 1 is a structural schematic view illustrating an evaporation source and two limiting plates in an embodiment of related art.

FIG. 2 is a structural schematic view of a display panel in a first embodiment of the present disclosure.

FIG. 3 is a structural schematic view of a pixel unit in a first embodiment of the present disclosure.

FIG. 4 is a cross-sectional structural schematic view of the pixel unit of FIG. 3 in a E-E direction.

FIG. 5 is a cross-sectional structural schematic view of the pixel unit of FIG. 3 in a F-F direction in an embodiment of the present disclosure.

FIG. 6 is a cross-sectional structural schematic view of the pixel unit of FIG. 3 in a F-F direction in another embodiment of the present disclosure.

FIG. 7 is a structural schematic view of the pixel unit in a second embodiment of the present disclosure.

FIG. 8 is a structural schematic view of the pixel unit in a third embodiment of the present disclosure.

FIG. 9 is a structural schematic view of the pixel unit in a fourth embodiment of the present disclosure.

FIG. 10 is a structural schematic view of the pixel unit in a fifth embodiment of the present disclosure.

FIG. 11 is a structural schematic view of the display panel in a second embodiment of the present disclosure.

FIG. 12 is a structural schematic view illustrating a first pixel unit and a second pixel unit in a first embodiment of the present disclosure.

FIG. 13 is a structural schematic view of the display panel in a third embodiment of the present disclosure.

FIG. 14 is a structural schematic view illustrating the first pixel unit and the second pixel unit in a second embodiment of the present disclosure.

FIG. 15 is a structural schematic view of the display panel in a fourth embodiment of the present disclosure.

FIG. 16 is a structural schematic view of the display panel in a fifth embodiment of the present disclosure.

FIG. 17 is a structural schematic view of the pixel unit in a sixth embodiment of the present disclosure.

FIG. 18 is a structural schematic view of the display panel in a sixth embodiment of the present disclosure.

FIG. 19 is a structural schematic view of the pixel unit in a seventh embodiment of the present disclosure.

FIG. 20 is a structural schematic view of the display panel in a seventh embodiment of the present disclosure.

FIG. 21 is a structural schematic view of the pixel unit in an eighth embodiment of the present disclosure.

### DETAILED DESCRIPTION

The technical solutions in some embodiments of the present disclosure may be explained in detail by combining the accompanying drawings.

In the following description, specific details such as specific system structures, interfaces, technologies, etc. are proposed for the purpose of illustration rather than limitation, so as to fully understand the present disclosure.

The technical solutions in some embodiments of the present disclosure may be clearly and completely described in conjunction with accompanying drawings in some embodiments of the present disclosure. Obviously, the described embodiments are only a part of the embodiments of the present disclosure, and not all embodiments. Based on the embodiments in the present disclosure, all other embodiments obtained by those of ordinary skill in the art without creative effort are within the scope of the present disclosure.

The terms “first”, “second”, and “third” in the present disclosure are only configured to describe purposes and cannot be understood as indicating or implying relative importance or implicit indicating the quantity of technical features indicated. Therefore, features limited to “first”, “second”, and “third” may explicitly or implicitly include at least one of these features. In the description of the present disclosure, “multiple” means at least two, such as two, three, etc., unless otherwise expressly and specifically qualified. All directional indications (such as up, down, left, right, front, rear, or the like) in some embodiments of the present disclosure are only configured to explain a relative position relationship between components in a specific posture (as shown in the accompanying drawings), a motion situation between the components in the specific posture (as shown in the accompanying drawings), or the like. If the specific posture is changed, the directional indication is also changed accordingly. In addition, the terms “including”, “comprising”, and “having”, as well as any variations of the terms “including”, “comprising”, and “having”, are intended to cover non-exclusive inclusions. For example, a process, method, system, product, or device that includes a series of operations or units is not limited to the listed operations or units, but optionally includes operations or units that are not listed, or optionally includes other operations or units that are inherent to these processes, methods, products, or devices.

The reference to “embodiment” in the present disclosure means that, specific features, structures, or characteristics described in conjunction with some embodiments may be included in at least one embodiment of the present disclosure. The phrase appearing in various positions in the specification does not necessarily refer to the same embodiment, nor is it an independent or alternative embodiment that is mutually exclusive with other embodiments. Those of ordinary skill in the art explicitly and implicitly understand that the embodiments described in the present disclosure may be combined with other embodiments.

An intended purpose of the present disclosure is to provide a display panel and a display device, which solves a problem of how to improve pixel opening rate of the display panel in related art.

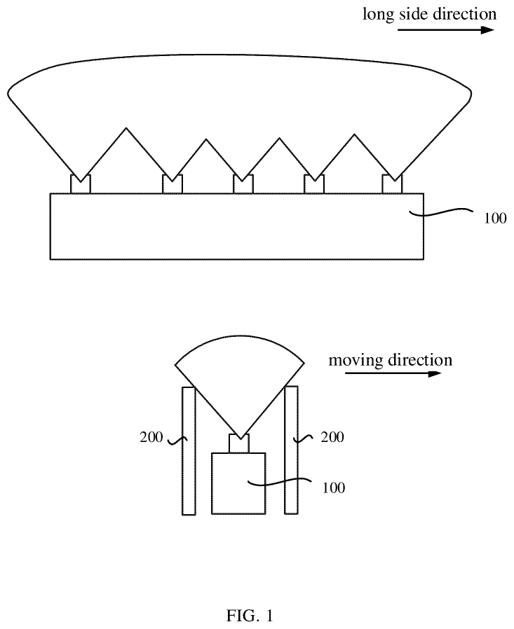

As illustrated in FIG. 1, FIG. 1 is a structural schematic view illustrating an evaporation source and two limiting plates in an embodiment of the related art.

In actual evaporation process, due to formation of an evaporation cloud in a long side direction of an evaporation source 100, an evaporation angle of an evaporation material cannot be controlled in the long side direction of the evaporation source 100. In a moving direction of the evaporation source 100 (i.e., a scanning direction of the evaporation source 100), an exit angle of the evaporation material may be controlled by using limiting plates 200, and each of two opposite sides of the evaporation source 100 is provided with one limiting plate 200. Thus, a side wall of an isolation structure that extends along the long side direction of the evaporation source 100 may be electrically connected to a cathode of a sub-pixel, and a side wall of the isolation structure that extends along the moving direction of the evaporation source 100 cannot be electrically connected to the cathode of the sub-pixel.

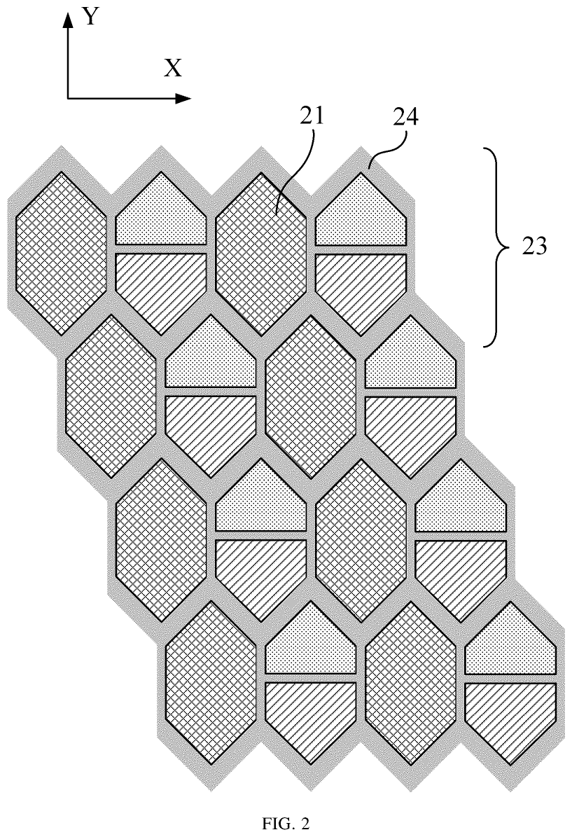

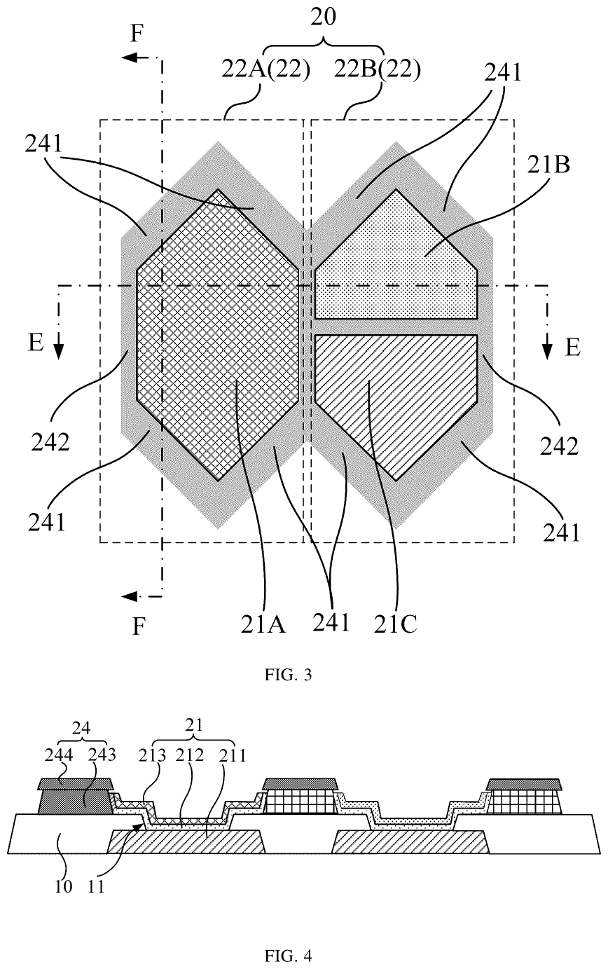

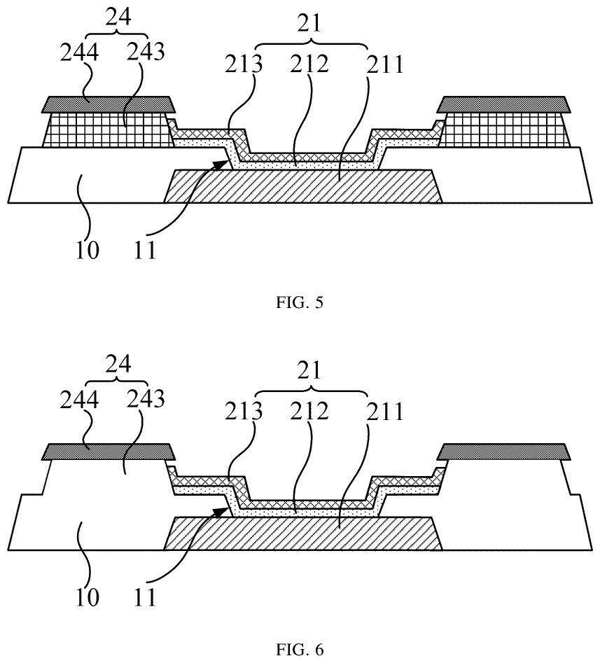

As illustrated in FIGS. 2 to 5, FIG. 2 is a structural schematic view of a display panel in a first embodiment of the present disclosure, FIG. 3 is a structural schematic view of a pixel unit in a first embodiment of the present disclosure, FIG. 4 is a cross-sectional structural schematic view of the pixel unit of FIG. 3 in a E-E direction, and FIG. 5 is a cross-sectional structural schematic view of the pixel unit of FIG. 3 in a F-F direction in an embodiment of the present disclosure.

Based on the above evaporation technology, the present disclosure provides a display panel. The display panel includes a pixel definition layer 10 and a plurality of pixel units 20. The pixel definition layer 10 defines a plurality of pixel openings 11. Each pixel unit 20 includes a plurality of sub-pixels 21 and a plurality of isolation structures 24. The plurality of sub-pixels 21 are disposed in the plurality of pixel openings 11, and the plurality of sub-pixels 21 are arranged in the plurality of pixel openings 11 one-to-one. The plurality of isolation structures 24 protrude from the pixel definition layer 10 and respectively surround at least one pixel opening 11. A plurality of side walls of each isolation structure 24 are defined as a first side wall 241 and a second side wall 242, respectively. In a direction parallel to the pixel definition layer 10, a thickness of the first side wall 241 is greater than that of the second side wall 242. In each isolation structure 24, the first side wall 241 includes: at least a portion of the side walls extending along a first direction X; and/or at least a portion of the side walls extending along a second direction Y. The first side wall 241 of at least one isolation structure 24 of each pixel unit 20 at least includes an inclined side wall. An extension direction of the inclined side wall intersects with the first direction X and the second direction Y, respectively. The first direction X is perpendicular to the second direction Y, and the extension direction of the inclined side wall, the first direction X, and the second direction Y are located in the same plane. The cathode 213 of each sub-pixel 21 is electrically connected to the corresponding inclined side wall, so that the cathode 213 of each sub-pixel 21 is electrically connected to the corresponding isolation structure 24; and/or, the cathode 213 of each sub-pixel 21 is electrically connected to the corresponding side wall extending along the first direction X, so that the cathode 213 of the sub-pixel 21 is electrically connected to the corresponding isolation structure 24.

In the present disclosure, electrical connections between the cathodes 213 of the plurality of sub-pixels 21 are achieved through the plurality of isolation structure 24. On this basis, the plurality of side walls of each isolation structure 24 are divided into the first side wall 241 and the second side wall 242. An area enclosed by an outer wall of each isolation structure 24 remains unchanged, the thickness of the first side wall 241 remains unchanged, and the thickness of the second side wall 242 is narrowed or reduces. Without affecting the electrical connection between each isolation structure 24 and the corresponding cathode 213 of each sub-pixel 21, the area enclosed by the isolation structure 24 is increased, thereby increasing pixel opening rate of the plurality of sub-pixels 21 and improving resolution of the display panel.

The pixel definition layer 10 is configured to limit positions of the plurality of sub-pixels 21. The plurality of pixel openings 11 on the pixel definition layer 10 are spaced apart from each other.

One sub-pixel 21 is disposed in one pixel opening 11. One sub-pixel 21 corresponds to one color pixel, and types of the color pixels corresponding to the plurality of sub-pixels 21 are not limited and may be selected based on actual needs.

Each sub-pixel 21 includes an anode 211, a light-emitting layer 212, and a cathode 213 sequentially stacked in a direction from the pixel definition layer 10 to the plurality of isolation structures 24. The light-emitting layer 212 and the cathode 213 are sequentially formed on an upper surface of the anode 211 through evaporating the evaporation source 100.

Each sub-pixel 21 includes an organic light-emitting diode (OLED).

A shape of each pixel opening 11 determines a shape and a size of the corresponding sub-pixel 21 disposed in each pixel opening 11. In some embodiments, in the direction parallel to the pixel definition layer 10, a contour shape of an end of each pixel opening 11 away from the corresponding isolation structure 24 is the shape of the corresponding sub-pixel 21 in each pixel opening 11. In the direction parallel to the pixel definition layer 10, the contour shape of the end of each pixel opening 11 away from the corresponding isolation structure 24 is similar to a contour shape of an end of each pixel opening 11 close to the corresponding isolation structure 24.

The plurality of isolation structures 24 are disposed on an upper surface of the pixel definition layer 10 and protrudes from the pixel definition layer 10. The plurality of isolation structures 24 respectively surround at least one pixel opening 11.

In response to the plurality of isolation structures 24 respectively surrounding the plurality of pixel openings 11, the corresponding sub-pixels 21 in the plurality of pixel openings 11 are electrically connected to each other, and each sub-pixel 21 corresponds to one color pixel, so as to avoid pixel crosstalk.

In response to the plurality of isolation structures 24 surrounding one pixel opening 11, an area enclosed by inner walls of the plurality of isolation structures 24 determine the shape of the pixel opening 11. In the direction parallel to the pixel definition layer 10, the shape of the area enclosed by the inner walls of the plurality of isolation structures 24 is similar to a shape of a cross-section of the pixel opening 11. That is, the shape of the area enclosed by the inner walls of the plurality of isolation structures 24 is similar to the shape of the sub-pixel 21. In some embodiments, there is a one-to-one correspondence between the plurality of side walls of each of the plurality of isolation structures 24 and side edges of each of the sub-pixel 21 enclosed by the each of the plurality of isolation structures 24, and the plurality of side walls of the plurality of isolation structures 24 are respectively parallel to the side edges of the sub-pixel 21.

In the present disclosure, one isolation structure 24 surrounding one pixel opening 11 is taken as an example, and distances between the side walls of the isolation structure 24 and the sub-pixel 21 enclosed by the isolation structure 24 are equal.

In some embodiments, the distances between the side walls of the isolation structure 24 and the sub-pixel 21 enclosed by the isolation structure 24 are not equal.

The side walls of each isolation structure 24 include an isolation column 243 and an eave structure 244 disposed on an upper surface of isolation column 243. The eave structure 244 covers the isolation column 243 and extends out of the isolation column 243 in the direction parallel to the pixel definition layer 10. That is, an orthographic projection of the eave structure 244 on the pixel definition layer 10 covers an orthographic projection of the isolation column 243 on the pixel definition layer 10. An area of the orthographic projection of the eave structure 244 on the pixel definition layer 10 is greater than an area of the orthographic projection of the isolation column 243 on the pixel definition layer 10. A structural design of the eave structure 244 allows the evaporation angle to be adjusted through edges of the eave structure 244, so that the evaporation angle may be adjusted through the eave structure 244 during evaporating the light-emitting layer 212 and the cathode 213 of the sub-pixel 21, thereby ensuring that the cathode 213 may cover the light-emitting layer 212 and have a good electrical connection with the corresponding isolation structure 24.

The eave structure 244 is conductive or insulating. A material of the eave structure 244 is not limited and may be selected based on actual needs.

As illustrated in FIG. 3, the plurality of side walls of each isolation structure 24 are divided into the first side wall 241 and the second side wall 242 that are connected to each other. The thickness of the first side wall 241 is greater than that of the second side wall 242. The electrical connection between each sub-pixel 21 and the corresponding isolation structure 24 is achieved through the first side wall 241, and the electrical connection between the plurality of isolation structures 24 is achieved through the first side wall 241, thereby achieving a full mesh connection between the plurality of sub-pixels 21, which facilitates uniformity of the cathodes 213.

The first side wall 241 of the present disclosure includes at least two side walls.

The isolation column 243 of the first side wall 241 is conductive and configured for being electrically connected to the corresponding sub-pixel 21 enclosed by the isolation structure 24. In response to the isolation column 243 being conductive, the isolation column 243 may not only be electrically connected to the corresponding sub-pixel 21, but also isolate the corresponding sub-pixel 21.

In the present disclosure, the eave structure 244 is insulating, and the isolation column 243 of the second side wall 242 is conductive. In response to the isolation column 243 of the second side wall 242 being conductive, entire isolation structures 24 is conductive. Thus, the cathodes 213 of the sub-pixels 21 have better full mesh connectivity, which facilitates the uniformity of the cathodes 213.

As illustrated in FIG. 6, FIG. 6 is a cross-sectional structural schematic view of the pixel unit of FIG. 3 in a F-F direction in another embodiment of the present disclosure.

In some embodiments, the isolation column 243 of the second side wall 242 is insulating, and the isolation column 243 of the second side wall 242 and the pixel definition layer 10 are formed by patterning the same insulating material. In response to the isolation column 243 of the second side wall 242 being insulating, the isolation column 243 only isolates the sub-pixel 21 and is not electrically connected to the cathode 213 of the sub-pixel 21. As illustrated in FIG. 6, the insulating isolation column 243 and the pixel definition layer 10 are formed by patterning the same insulating material, which may simplify preparation process of the isolation column 243.

A material of conductive isolation column 243 or a material of insulating isolation column 243 is not limited, and may be selected based on actual needs. In response to the isolation column 243 being insulating, the material of the isolation column 243 may be other insulating materials that are different from the material of the pixel definition layer 10.

In the present disclosure, surfaces of all isolation columns 243 away from the pixel definition layer 10 are located in the same plane, so as to simplify the preparation process of the isolation columns 243.

The side walls of the isolation structures 24 may also be other structures.

In each isolation structure 24, the first side wall 241 includes: at least a portion of the side walls extending along the first direction X; and/or at least a portion of the side walls extending along the second direction Y. The first side wall 241 of at least one isolation structure 24 of each pixel unit 20 at least includes the inclined side wall. That is, each pixel unit 20 must have an isolation structure 24, and the first side wall 241 of this isolation structure 24 includes the inclined side wall. The sub-pixel 21 is electrically connected to the inclined side wall, so that the sub-pixel 21 is electrically connected to the corresponding isolation structure 24; and/or, the sub-pixel 21 is electrically connected to the side wall extended along the first direction X, so that the sub-pixel 21 is electrically connected to the corresponding isolation structure 24.

The extension direction of the inclined side wall intersects with the first direction X and the second direction Y, respectively. The first direction X is perpendicular to the second direction Y, and the extension direction of the inclined side wall, the first direction X, and the second direction Y are located in the same plane.

In some embodiments, the first direction X represents the long side direction of the evaporation source 100, and the second direction Y represents the moving direction of the evaporation source 100.

Based on the evaporation technology in the related art, the present disclosure utilizes the principle that the side wall extending along the first direction X may be electrically connected to the cathode 213 of the sub-pixel 21 enclosed by the isolation structure 24, and the inclined side wall intersecting with the first direction X and the second direction Y may also be electrically connected to the cathode 213 of the sub-pixel 21 enclosed by the isolation structure 24. The area enclosed by the outer wall of the isolation structure 24 remains unchanged, the thickness of the first side wall 241 is greater than that of the second side wall 242, thereby increasing the area enclosed by the inner wall of the isolation structure 24 and improving the pixel opening rate.

Compared with a design that the thickness of the side wall extending along the first direction X only remains unchanged, the first side walls 241 of the isolation structures 24 in a single pixel unit 20 in the present disclosure may include more types of side walls, and the isolation structures 24 have more arrangement modes.

Each pixel unit 20 includes at least one pixel group 22. At least one sub-pixel 21 and one isolation structure 24 surrounding the sub-pixel 21 form one pixel group 22. A shape of each pixel group 22 is a hexagon. The hexagon has an axisymmetric or centrosymmetric shape. The pixel group 22 includes side edges extending along the first direction X or the second direction Y.

The pixel group 22 is set as the hexagon and the hexagon is set as the axisymmetric or centrosymmetric shape, so that the pixel units 20 may be arranged compactly, thereby improving the resolution of the display panel.

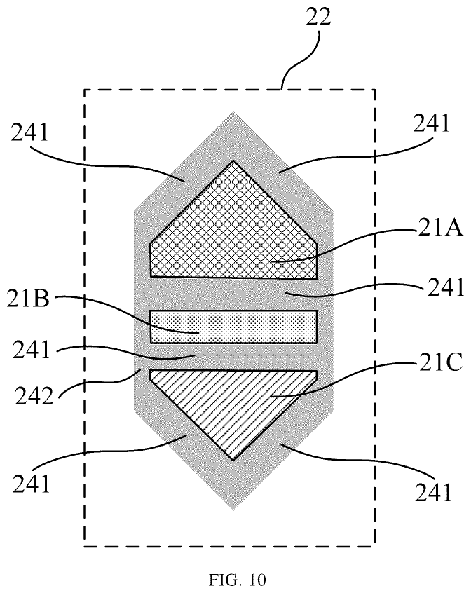

In response to each pixel unit 20 including one pixel group 22 (as illustrated FIG. 10), the pixel unit 20 is the hexagon. In response to the pixel unit 20 including a plurality of pixel groups 22, the plurality of pixel groups 22 are disposed side by side and in direct contact with each other along the first direction X or the second direction Y, and a side of one pixel group 22 and a side of the adjacent pixel group 22 close to the side of the pixel group 22 are parallel to each other. That is, a first pixel group 22 includes a first side, a second pixel group 22 that is adjacent to the first pixel group 22 includes a second side, the first side of the first pixel group 22 is close to the second pixel group 22, the second side of the second pixel group 22 is close to the first pixel group 22, and the first side of the first pixel group 22 and the second side of the second pixel group 22 are parallel to each other. Thus, the pixel units 20 may be arranged compactly, thereby improving the resolution of the display panel.

In some embodiments, in each pixel unit 20, a side of one sub-pixel 21 and a side of the adjacent sub-pixel 21 close to the side of the sub-pixel 21 are parallel to each other. That is, one sub-pixel 21 includes a first side, another sub-pixel 21 that is adjacent to the one sub-pixel 21 includes a second side, the first side of the one first sub-pixel 21 is close to the another second sub-pixel 21, the second side of the another second sub-pixel 21 is close to the one first sub-pixel 21, and the first side of the one first sub-pixel 21 and the second side of the another second sub-pixel 21 are parallel to each other. Each pixel group 22 includes an inclined side edge and a side edge extending along the second direction Y. An extension direction of the inclined side edge intersects with the first direction X and the second direction Y. Each pixel unit 20 includes three sub-pixels 21 of different colors, which are defined as a first sub-pixel 21A, a second sub-pixel 21B, and a third sub-pixel 21C, respectively. The first sub-pixel 21A and the isolation structure 24 surrounding the first sub-pixel 21A form a first pixel group 22A. The second sub-pixel 21B, the isolation structure 24 surrounding the second sub-pixel 21B, the third sub-pixel 21C, and the isolation structure 24 surrounding the third sub-pixel 21C form a second pixel group 22B. In the second pixel group 22B, the third sub-pixel 21C and the second sub-pixel 21B share a side wall of the isolation structure 24 that extends along the first direction X, and the third sub-pixel 21C is flush with the second sub-pixel 21B in the second direction Y. The side walls extending along the second direction Y of two adjacent isolation structures 24 in the first direction X overlap in a direction perpendicular to the pixel definition layer 10.

In the second pixel group 22B, the third sub-pixel 21C and the second sub-pixel 21B share the side wall of the isolation structure 24 extending along the first direction X, which means that the side wall extending along the first direction X of the isolation structure 24 that surrounds the third sub-pixel 21C also serves as the side wall extending along the first direction X of the isolation structure 24 that surrounds the second sub-pixel 21B. The third sub-pixel 21C is flush with the second sub-pixel 21B in the second direction Y, which means that a side edge of the second sub-pixel 21B away from the first sub-pixel 21A is on the same line as a side edge of the third sub-pixel 21C away from the first sub-pixel 21A, and a side edge of the second sub-pixel 21B close to the first sub-pixel 21A is on the same line as a side edge of the third sub-pixel 21C close to the first sub-pixel 21A, as illustrated in FIG. 3.

The pixel group 22 in some embodiments is symmetrically disposed along the first direction X and symmetrically disposed along the second direction Y, and also has a center symmetric shape. The second sub-pixel 21B and the third sub-pixel 21C are symmetrically disposed along the second direction Y, as illustrated in FIG. 3.

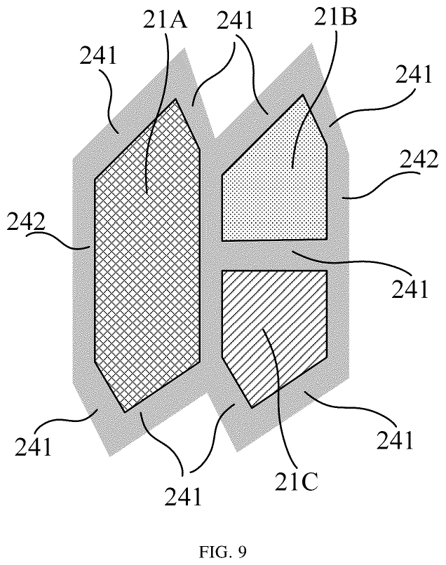

As illustrated in FIGS. 2 and 7 to 10, FIG. 7 is a structural schematic view of the pixel unit in a second embodiment of the present disclosure, FIG. 8 is a structural schematic view of the pixel unit in a third embodiment of the present disclosure, FIG. 9 is a structural schematic view of the pixel unit in a fourth embodiment of the present disclosure, and FIG. 10 is a structural schematic view of the pixel unit in a fifth embodiment of the present disclosure.

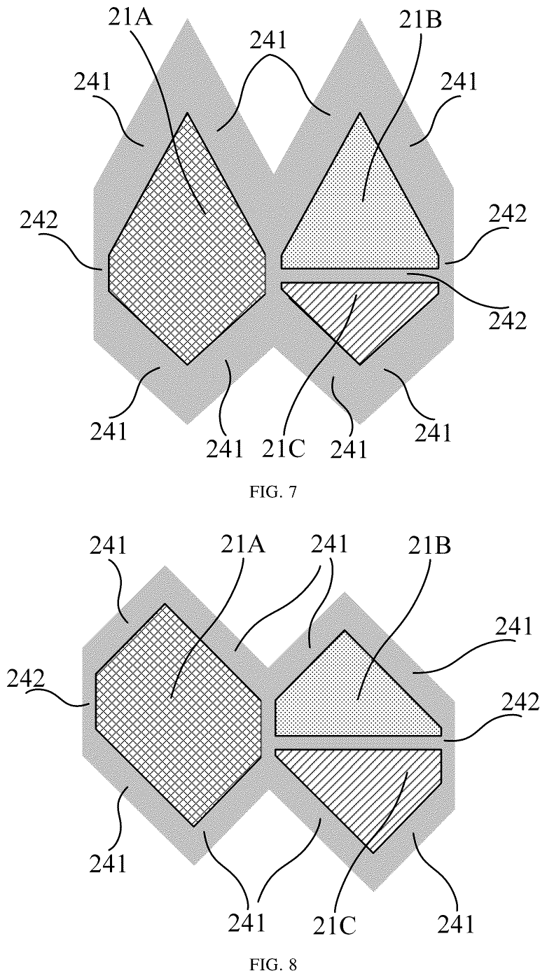

In some embodiments, the pixel group 22 may be symmetric only along the first direction X or the second direction Y (as illustrated FIG. 7), or only has the center symmetric shape (as illustrated FIGS. 8 and 9), or symmetric along the first direction X and the second direction Y respectively (as illustrated FIG. 10), which is not limited and may be selected based on actual needs. The sub-pixels 21 of the pixel group 22 may also be asymmetric shapes (as illustrated in FIGS. 8 and 9).

In some embodiments, the plurality of pixel units 20 are repeated and disposed side by side in the first direction X, to form a pixel unit row 23. A plurality of pixel unit rows 23 are repeated in the second direction Y, and two adjacent pixel unit rows 23 are disposed in a staggered manner in the first direction X. That is, structures of all pixel units 20 in the display panel are the same.

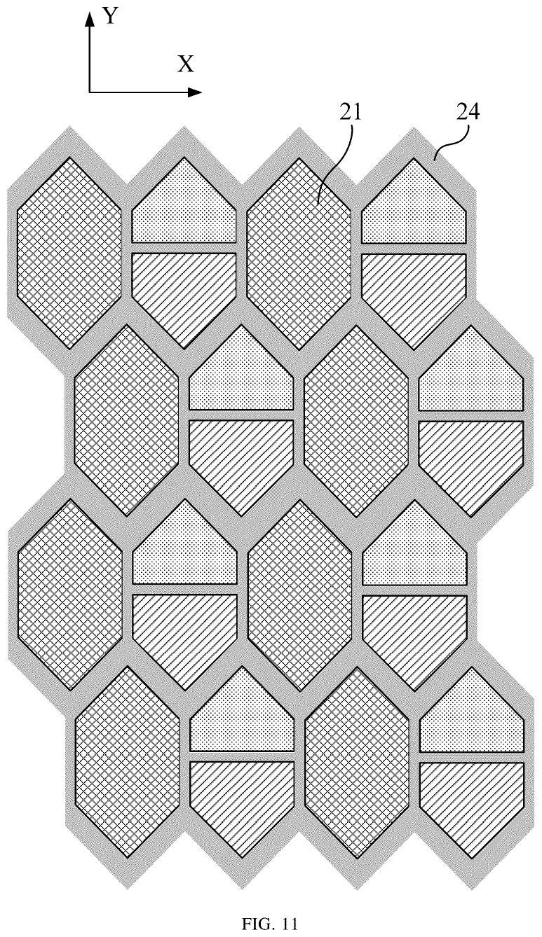

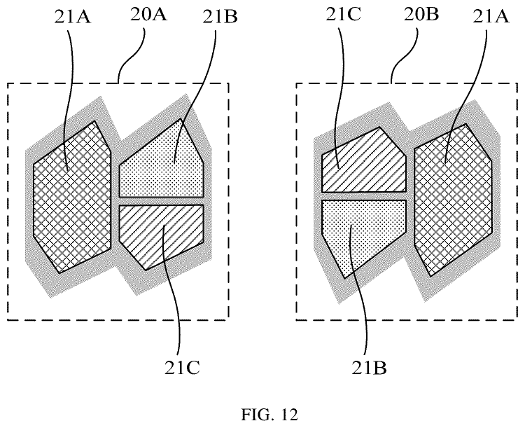

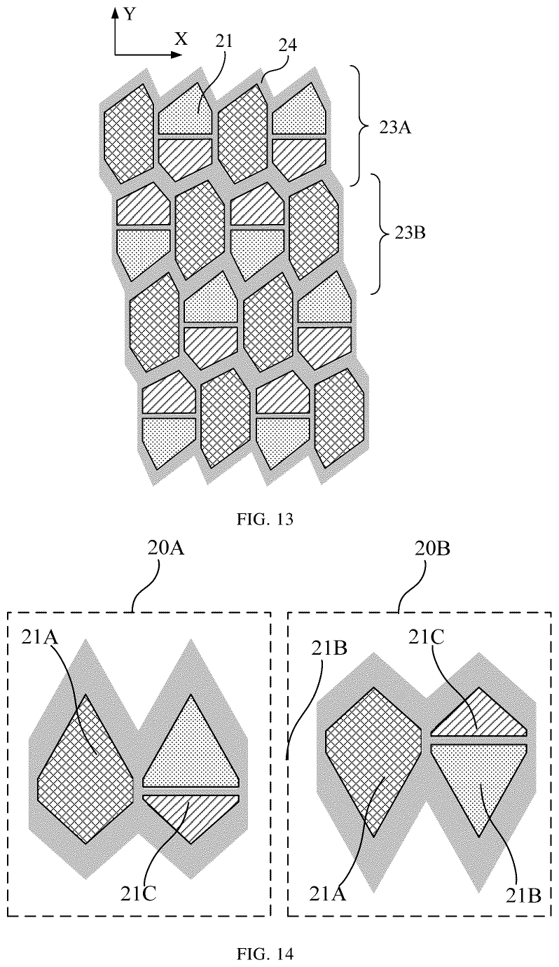

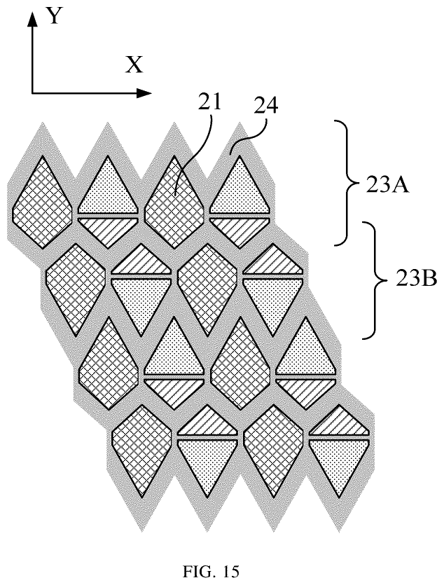

As illustrated in FIGS. 11 to 15, FIG. 11 is a structural schematic view of the display panel in a second embodiment of the present disclosure, FIG. 12 is a structural schematic view illustrating a first pixel unit and a second pixel unit in a first embodiment of the present disclosure, FIG. 13 is a structural schematic view of the display panel in a third embodiment of the present disclosure, FIG. 14 is a structural schematic view illustrating the first pixel unit and the second pixel unit in a second embodiment of the present disclosure, and FIG. 15 is a structural schematic view of the display panel in a fourth embodiment of the present disclosure.

In some embodiments, as illustrated in FIG. 11, odd row pixel unit row 23 may be arranged in a first array, even row pixel unit row 23 may be arranged in a second array, and adjacent odd row pixel unit row 23 and even row pixel unit row 23 are arranged in a staggered manner in the first direction X. In some embodiments, the plurality of pixel units 20 may be defined as a first pixel unit 20A and a second pixel unit 20B, respectively. The second pixel unit 20B (as illustrated in FIGS. 12 and 14) may be formed by centrally or axially symmetrizing the first pixel unit 20A. A plurality of first pixel units 20A are repeatedly arranged along the first direction X, to form a first pixel unit row 23A. A plurality of second pixel units 20B are repeatedly arranged along the first direction X, to form a second pixel unit row 23B. The first pixel unit row 23A and the second pixel unit row 23B are alternately arranged along the second direction Y.

In some embodiments, in each isolation structure 24, the first side wall 241 includes all inclined side walls. In the first direction X, two adjacent first side walls 241 are in direct contact with each other and electrically connected to each other. All sub-pixels 21 are electrically connected to the inclined side walls, so that all sub-pixels 21 are electrically connected to the isolation structures 24.

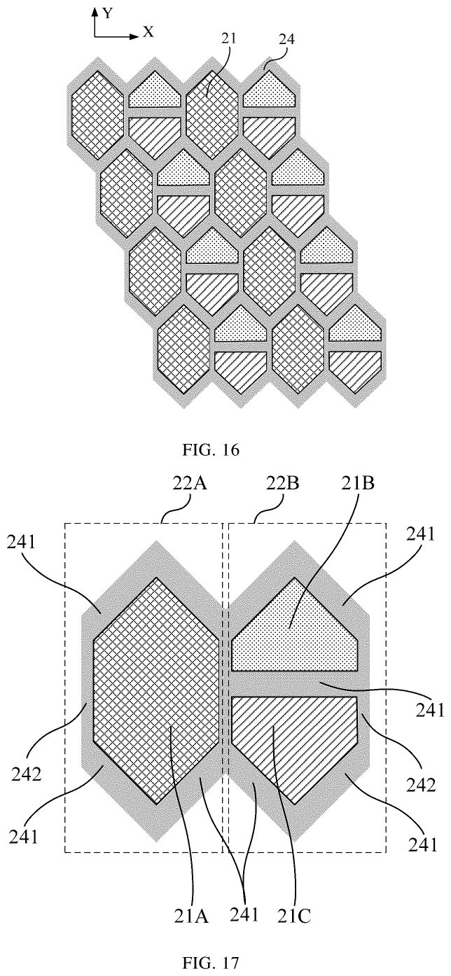

As illustrated in FIGS. 16 and 17, FIG. 16 is a structural schematic view of the display panel in a fifth embodiment of the present disclosure, and FIG. 17 is a structural schematic view of the pixel unit in a sixth embodiment of the present disclosure.

In some embodiments, in the second pixel group 22B, the first side wall 241 of the isolation structure 24 further includes the side wall extending along the first direction X. The first sub-pixel 21A is electrically connected to the inclined side wall, so that the first sub-pixel 21A is electrically connected to the isolation structure 24. The second sub-pixel 21B and the third sub-pixel 21C are electrically connected to the side wall extending along the first direction X, so that the second sub-pixel 21B and the third sub-pixel 21C are electrically connected to the isolation structure 24. Thus, the good electrical connection between the sub-pixels 21 and the isolation structures 24 may further enhanced, so as to reduce load on each cathode 213.

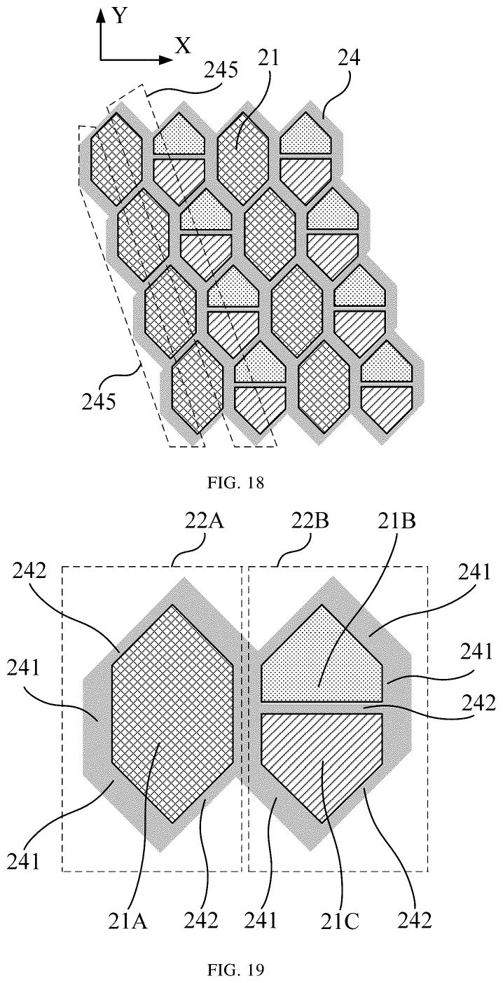

As illustrated in FIGS. 18 and 19, FIG. 18 is a structural schematic view of the display panel in a sixth embodiment of the present disclosure, and FIG. 19 is a structural schematic view of the pixel unit in a seventh embodiment of the present disclosure.

The display panel in sixth embodiment of the present disclosure has a similar structure to the display panel in the first embodiment of the present disclosure, except that in each isolation structure 24, the first side wall 241 includes the side walls extending along the second direction Y and a portion of the inclined side walls. In the second direction Y, every two first side walls 241 of the plurality of first side walls 241 are in direct contact with each other, so as to form a plurality of side wall groups 245. The side wall groups 245 are configured to electrically connect two adjacent pixel groups 22 in the second direction Y. In the first direction X, the side wall groups 245 are spaced apart from each other.

In some embodiments, in each isolation structure 24, the first side wall 241 includes the side walls extending along the second direction Y and a portion of the inclined side walls. In the second direction Y, every two first side walls 241 of the plurality of first side walls 241 are in direct contact with each other, so as to form the plurality of side wall groups 245. The side wall groups 245 are configured to electrically connect two adjacent pixel groups 22 in the second direction Y. In the first direction X, the side wall groups 245 are spaced apart from each other. All sub-pixels 21 are electrically connected to the inclined side walls, so that all sub-pixels 21 are electrically connected to the isolation structures 24.

The technical solutions in above embodiments may also improve the pixel opening rate.

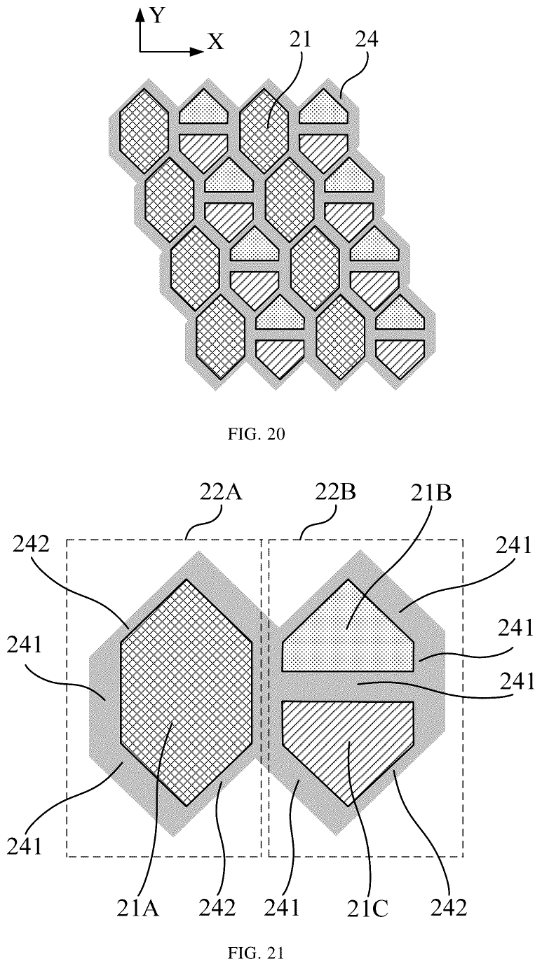

As illustrated in FIGS. 20 and 21, FIG. 20 is a structural schematic view of the display panel in a seventh embodiment of the present disclosure, and FIG. 21 is a structural schematic view of the pixel unit in an eighth embodiment of the present disclosure.

In some embodiments, in the second pixel group 22B, the first side wall 241 of the isolation structure 24 further includes the side wall extending along the first direction X. The first sub-pixel 21A is electrically connected to the inclined side wall, so that the first sub-pixel 21A is electrically connected to the isolation structure 24. The second sub-pixel 21B is electrically connected to the inclined side wall and the side wall extending along the first direction X, so that the second sub-pixel 21B is electrically connected to the isolation structure 24, thereby further enhancing the good electrical connection between the sub-pixels 21 and the isolation structures 24.

The arrangement of the sub-pixels 21 in the present disclosure includes but is not limited to above arrangement, and layout of the side walls of the first side wall 241 of the present disclosure includes but is not limited to above layout.

The present disclosure further provides a display device, and the display device includes any one of above display panels.

Different from the related art, the effects of the present disclosure are as follows. The present disclosure provides a display panel and a display device. The display panel includes a pixel definition layer and a plurality of pixel units. The pixel definition layer defines a plurality of pixel openings. Each of the plurality of pixel units includes a plurality of sub-pixels and a plurality of isolation structures. The plurality of sub-pixels are arranged in the plurality of pixel openings one-to-one. The plurality of isolation structures protrude from the pixel definition layer and respectively surround the plurality of pixel openings. A plurality of side walls of each of the plurality of isolation structures are defined as a first side wall and a second side wall, respectively. In a direction parallel to the pixel definition layer, a thickness of the first side wall is greater than that of the second side wall. In each of the plurality of isolation structures, the first side wall includes at least a portion of the side walls extending along a first direction, and/or at least a portion of the side walls extending along a second direction. In each of the plurality of pixel units, the first side wall of at least one isolation structure at least includes an inclined side wall; an extension direction of the inclined side wall intersects with the first direction and the second direction, respectively; and the first direction is perpendicular to the second direction; the extension direction of the inclined side wall, the first direction, and the second direction are located in the same plane. A cathode of each of the plurality of sub-pixels is electrically connected to corresponding inclined side wall, so that the cathode of each of the plurality of sub-pixels is electrically connected to a corresponding one of the plurality of isolation structures; and/or, the cathode of each of the plurality of sub-pixels is electrically connected to corresponding side wall extending along the first direction, so that the cathode of each of the plurality of sub-pixels is electrically connected to the corresponding one of the plurality of isolation structures. In the present disclosure, electrical connections between the cathodes of the plurality of sub-pixels are achieved through the plurality of isolation structure. On this basis, the plurality of side walls of each isolation structure are divided into the first side wall and the second side wall. An area enclosed by an outer wall of each isolation structure remains unchanged, the thickness of the first side wall remains unchanged, and the thickness of the second side wall is narrowed or reduces. Without affecting the electrical connection between each isolation structure and the corresponding cathode of each sub-pixel, the area enclosed by the isolation structure is increased, thereby increasing pixel opening rate of the plurality of sub-pixels and improving resolution of the display panel.

In above embodiments, description of each embodiment has its own emphasis. Parts that are not detailed in one embodiment may refer to relevant descriptions of other embodiments.

The above descriptions are only some embodiments of the present disclosure, and are not intended to limit the scope of the present disclosure. Any equivalent structure or equivalent flow transformation made by using the contents of the specification and accompanying drawings of the present disclosure, or directly or indirectly applied to other related technical fields, is included in the scope of the patent protection of the present disclosure.

What is claimed is:

1. A display panel, comprising:
a pixel definition layer defining a plurality of pixel openings;
a plurality of pixel units, wherein each of the plurality of pixel units comprises:
a plurality of sub-pixels, arranged in the plurality of pixel openings one-to-one; and
a plurality of isolation structures, protruding from the pixel definition layer and respectively surrounding the plurality of pixel openings; wherein a plurality of side walls of each of the plurality of isolation structures are defined as a first side wall and a second side wall, respectively;
in a direction parallel to the pixel definition layer, a thickness of the first side wall is greater than that of the second side wall; in each of the plurality of isolation structures, the first side wall comprises:
at least a portion of the side walls extending along a first direction; and/or,
at least a portion of the side walls extending along a second direction;
wherein in each of the plurality of pixel units, the first side wall of at least one isolation structure at least comprises an inclined side wall; an extension direction of the inclined side wall intersects with the first direction and the second direction, respectively; the first direction is perpendicular to the second direction; and the extension direction of the inclined side wall, the first direction, and the second direction are located in the same plane;
wherein a cathode of each of the plurality of sub-pixels is electrically connected to corresponding inclined side wall, so that the cathode of each of the plurality of sub-pixels is electrically connected to a corresponding one of the plurality of isolation structures; and/or, the cathode of each of the plurality of sub-pixels is electrically connected to corresponding side wall extending along the first direction, so that the cathode of each of the plurality of sub-pixels is electrically connected to the corresponding one of the plurality of isolation structures.

2. The display panel according to claim 1, wherein each of the plurality of isolation structures surrounds a corresponding one of the plurality of pixel openings; there is a one-to-one correspondence between the plurality of side walls of each of the plurality of isolation structures and side edges of each of the plurality of sub-pixels enclosed by the each of the plurality of isolation structures, and the plurality of side walls of the plurality of isolation structures are respectively parallel to the side edges of the plurality of sub-pixels;
each of the plurality of sub-pixels comprises an anode, a light-emitting layer, and a cathode sequentially stacked; the light-emitting layer and the cathode are sequentially formed on an upper surface of the anode by evaporating an evaporation source; and the first direction is a long side direction of the evaporation source, and the second direction is a moving direction of the evaporation source.

3. The display panel according to claim 2, wherein each of the plurality of pixel units comprises at least one pixel group, at least one sub-pixel and one of the plurality of isolation structures surrounding corresponding sub-pixel form a pixel group, a shape of each pixel group is a hexagon, the hexagon has an axisymmetric or centrosymmetric shape, and each pixel group comprises a side edge extending along the first direction or the second direction; and
each of the plurality of pixel units comprises a plurality of pixel groups, the plurality of pixel groups are disposed side by side and in direct contact with each other along the first direction or the second direction, and a side of one pixel group and a side of an adjacent pixel group close to the side of the pixel group are parallel to each other.

4. The display panel according to claim 3, wherein:
the plurality of pixel units are repeated and disposed side by side in the first direction to form a pixel unit row, and a plurality of the pixel unit rows are repeated in the second direction; or
the plurality of pixel units are defined as a first pixel unit and a second pixel unit, respectively; the second pixel unit is formed by centrally or axially symmetrizing the first pixel unit; a plurality of the first pixel units are repeatedly arranged along the first direction, to form a first pixel unit row; a plurality of the second pixel units are repeatedly arranged along the first direction, to form a second pixel unit row; and the first pixel unit row and the second pixel unit row are alternately arranged along the second direction.

5. The display panel according to claim 3, wherein in the pixel unit, a side of one of the plurality of sub-pixels and a side of an adjacent sub-pixel close to the side of the one of the plurality of sub-pixels are parallel to each other; and
each pixel group comprises an inclined side edge and a side edge extending along the second direction, and an extension direction of the inclined side edge intersects with the first direction and the second direction; each of the plurality of pixel units comprises three sub-pixels of different colors, which are defined as a first sub-pixel, a second sub-pixel, and a third sub-pixel, respectively; the first sub-pixel and one of the plurality of isolation structures surrounding the first sub-pixel form a first pixel group; the second sub-pixel, one of the plurality of isolation structures surrounding the second sub-pixel, the third sub-pixel, and one of the plurality of isolation structures surrounding the third sub-pixel form a second pixel group; in the second pixel group, the third sub-pixel and the second sub-pixel share a side wall of the plurality of isolation structures extending along the first direction, and the third sub-pixel is flush with the second sub-pixel in the second direction; and side walls extending along the second direction of two adjacent isolation structures in the first direction overlap in a direction perpendicular to the pixel definition layer.

6. The display panel according to claim 5, wherein:
in each of the plurality of isolation structures, the first side wall comprises all inclined side walls; in the first direction, two adjacent first side walls are in direct contact with each other and electrically connected to each other; or
in each of the plurality of isolation structures, the first side wall comprises the side walls extending along the second direction and a portion of the inclined side walls; in the second direction, every two first side walls of a plurality of first side walls are in direct contact with each other, so as to form a plurality of side wall groups; the plurality of side wall groups are configured to electrically connect two adjacent pixel groups in the second direction; and in the first direction, the plurality of side wall groups are spaced apart from each other.

7. The display panel according to claim 6, wherein in the second pixel group, the first side wall of each of the plurality of isolation structures further comprises a side wall extending along the first direction.

8. The display panel according to claim 1, wherein each of the plurality of side walls of each of the plurality of isolation structures comprises an isolation column and an eave structure disposed on an upper surface of isolation column, and the eave structure covers the isolation column and extends out of the isolation column in the direction parallel to the pixel definition layer; and the eave structure is conductive or insulating, and the isolation column of the first side wall is conductive and configured for being electrically connected to one of the plurality of sub-pixels that is enclosed by the corresponding one of the plurality of isolation structures.

9. The display panel according to claim 8, wherein the isolation column of the second side wall is conductive; or
the isolation column of the second side wall is insulating, and the isolation column of the second side wall and the pixel definition layer are formed by patterning the same insulating material.

10. The display panel according to claim 8, wherein an area of an orthographic projection of the eave structure on the pixel definition layer is greater than an area of an orthographic projection of the isolation column on the pixel definition layer.

11. A display device, comprising:
a display panel, comprising:
a pixel definition layer defining a plurality of pixel openings;
a plurality of pixel units, wherein each of the plurality of pixel units comprises:
a plurality of sub-pixels, arranged in the plurality of pixel openings one-to-one; and
a plurality of isolation structures, protruding from the pixel definition layer and respectively surrounding the plurality of pixel openings; wherein a plurality of side walls of each of the plurality of isolation structures are defined as a first side wall and a second side wall, respectively; in a direction parallel to the pixel definition layer, a thickness of the first side wall is greater than that of the second side wall; in each of the plurality of isolation structures, the first side wall comprises:
at least a portion of the side walls extending along a first direction; and/or,
at least a portion of the side walls extending along a second direction;
wherein in each of the plurality of pixel units, the first side wall of at least one isolation structure at least comprises an inclined side wall; an extension direction of the inclined side wall intersects with the first direction and the second direction, respectively; the first direction is perpendicular to the second direction; and the extension direction of the inclined side wall, the first direction, and the second direction are located in the same plane;
wherein a cathode of each of the plurality of sub-pixels is electrically connected to corresponding inclined side wall, so that the cathode of each of the plurality of sub-pixels is electrically connected to a corresponding one of the plurality of isolation structures; and/or, the cathode of each of the plurality of sub-pixels is electrically connected to corresponding side wall extending along the first direction, so that the cathode of each of the plurality of sub-pixels is electrically connected to the corresponding one of the plurality of isolation structures.

12. The display device according to claim 11, wherein each of the plurality of isolation structures surrounds a corresponding one of the plurality of pixel openings; there is a one-to-one correspondence between the plurality of side walls of each of the plurality of isolation structures and side edges of each of the plurality of sub-pixels enclosed by the each of the plurality of isolation structures, and the plurality of side walls of the plurality of isolation structures are respectively parallel to the side edges of the plurality of sub-pixels;
each of the plurality of sub-pixels comprises an anode, a light-emitting layer, and a cathode sequentially stacked; the light-emitting layer and the cathode are sequentially formed on an upper surface of the anode by evaporating an evaporation source; and the first direction is a long side direction of the evaporation source, and the second direction is a moving direction of the evaporation source.

13. The display device according to claim 12, wherein each of the plurality of pixel units comprises at least one pixel group, at least one sub-pixel and one of the plurality of isolation structures surrounding corresponding sub-pixel form a pixel group, a shape of each pixel group is a hexagon, the hexagon has an axisymmetric or centrosymmetric shape, and each pixel group comprises a side edge extending along the first direction or the second direction; and
each of the plurality of pixel units comprises a plurality of pixel groups, the plurality of pixel groups are disposed side by side and in direct contact with each other along the first direction or the second direction, and a side of one pixel group and a side of an adjacent pixel group close to the side of the pixel group are parallel to each other.

14. The display device according to claim 13, wherein:
the plurality of pixel units are repeated and disposed side by side in the first direction to form a pixel unit row, and a plurality of the pixel unit rows are repeated in the second direction; or
the plurality of pixel units are defined as a first pixel unit and a second pixel unit, respectively; the second pixel unit is formed by centrally or axially symmetrizing the first pixel unit; a plurality of the first pixel units are repeatedly arranged along the first direction, to form a first pixel unit row; a plurality of the second pixel units are repeatedly arranged along the first direction, to form a second pixel unit row; and the first pixel unit row and the second pixel unit row are alternately arranged along the second direction.

15. The display device according to claim 13, wherein in the pixel unit, a side of one of the plurality of sub-pixels and a side of an adjacent sub-pixel close to the side of the one of the plurality of sub-pixels are parallel to each other; and
each pixel group comprises an inclined side edge and a side edge extending along the second direction, and an extension direction of the inclined side edge intersects with the first direction and the second direction; each of the plurality of pixel units comprises three sub-pixels of different colors, which are defined as a first sub-pixel, a second sub-pixel, and a third sub-pixel, respectively; the first sub-pixel and one of the plurality of isolation structures surrounding the first sub-pixel form a first pixel group; the second sub-pixel, one of the plurality of isolation structures surrounding the second sub-pixel, the third sub-pixel, and one of the plurality of isolation structures surrounding the third sub-pixel form a second pixel group; in the second pixel group, the third sub-pixel and the second sub-pixel share a side wall of the plurality of isolation structures extending along the first direction, and the third sub-pixel is flush with the second sub-pixel in the second direction; and side walls extending along the second direction of two adjacent isolation structures in the first direction overlap in a direction perpendicular to the pixel definition layer.

16. The display device according to claim 15, wherein:
in each of the plurality of isolation structures, the first side wall comprises all inclined side walls; in the first direction, two adjacent first side walls are in direct contact with each other and electrically connected to each other; or
in each of the plurality of isolation structures, the first side wall comprises the side walls extending along the second direction and a portion of the inclined side walls; in the second direction, every two first side walls of a plurality of first side walls are in direct contact with each other, so as to form a plurality of side wall groups; the plurality of side wall groups are configured to electrically connect two adjacent pixel groups in the second direction; and in the first direction, the plurality of side wall groups are spaced apart from each other.

17. The display device according to claim 16, wherein in the second pixel group, the first side wall of each of the plurality of isolation structures further comprises a side wall extending along the first direction.

18. The display device according to claim 11, wherein each of the plurality of side walls of each of the plurality of isolation structures comprises an isolation column and an eave structure disposed on an upper surface of isolation column, and the eave structure covers the isolation column and extends out of the isolation column in the direction parallel to the pixel definition layer; and the eave structure is conductive or insulating, and the isolation column of the first side wall is conductive and configured for being electrically connected to one of the plurality of sub-pixels that is enclosed by the corresponding one of the plurality of isolation structures.

19. The display device according to claim 18, wherein the isolation column of the second side wall is conductive; or
the isolation column of the second side wall is insulating, and the isolation column of the second side wall and the pixel definition layer are formed by patterning the same insulating material.

20. The display device according to claim 18, wherein an area of an orthographic projection of the eave structure on the pixel definition layer is greater than an area of an orthographic projection of the isolation column on the pixel definition layer.
